(19) United States
(12) Patent Application Publication
(10) Pub. No.: US 2009/0001403 A1
(43) Pub. Date: Jan. 1, 2009

(54) INDUCTIVELY EXCITED QUANTUM DOT LIGHT EMITTING DEVICE

(75) Inventors: Andrew F. Skipor, West Chicago, IL (US); Rick Latella, Woodstock, IL (US)

Correspondence Address: INGRASSIA FISHER & LORENZ, P.C. (MOT), 7010 E. Cochise Road, SCOTTSDALE, AZ, 85253, US

(73) Assignee: MOTOROLA, INC., Schaumburg, IL (US)

(21) Appl. No.: 11/770,939

(22) Filed: Jun. 29, 2007

(51) Int. Cl. H01L 33/00; G21G 4/00

(52) U.S. Cl. 257/99; 250/493.1; 257/E33.053

(57) ABSTRACT

A method and apparatus is provided for activating a layer (208, 308, 408) of free standing quantum dots. The apparatus comprises a first coil (216, 316, 426) disposed contiguous to a light emitting device (200, 300, 400, 612) including the free standing quantum dots. An alternating current is supplied to the coil (216, 316, 426) for generating an electric field, and the plurality of free standing quantum dots are subjected to the electric field thereby causing photons to be emitted therefrom. A structure (214, 328), such as a housing (620) of a portable electronic device (610, 710) may be positioned either, when opaque, between the light emitting device (300, 400) and the coil (316, 426), or, when transparent, on a side of the light emitting device (200) opposed to the coil (216).

### FIELD OF THE INVENTION

The present disclosure generally relates to light emitting displays and more particularly to free standing quantum dot light emitting display.

### BACKGROUND OF THE INVENTION

The market for personal portable electronic devices, for example, cell phones, personal digital assistants (PDA's), digital cameras, and music playback devices (MP3), is very competitive. Manufactures are constantly improving their product with each model in an attempt to cut costs and production requirements.

In many portable electronic devices, such as mobile communication devices, displays present information to a user. For a simple icon display on the surface of a housing, for example, light emitting diodes have provided light through a small portion of a surface of the housing to illuminate an icon to a user.

Free standing quantum dots (FSQDs) are semiconductor nanocrystallites whose radii are smaller than the bulk exciton Bohr radius and constitute a class of materials intermediate between molecular and bulk forms of matter. FSQDs are known for the unique properties that they possess as a result of both their small size and their high surface area to volume ratio. For example, FSQDs typically have larger absorption cross-sections than comparable organic dyes, higher quantum yields, better chemical and photo-chemical stability, narrower and more symmetric emission spectra, and a larger Stokes shift. Furthermore, the absorption and emission properties vary with the particle size and can be systematically tailored. It has been found that a Cadmium Selenium (CdSe) quantum dot, for example, can emit light in any monochromatic, visible color, where the particular color characteristic of that dot is dependent on the size of the quantum dot, (i.e., size tunable band gap).

FSQDs are easily incorporated (solubalized or dispersed) into or onto other materials such as polymers and polymer composites because solution processing of inorganic nanocrystals is made possible by a capping layer of organic capping groups on the surface of the FSQDs. This capping layer may be tailored to control solubility, external chemistry, and particle spacing. FSQDs are highly soluble and have little degradation over time. These properties allow FSQD polymers and polymer composites to provide very bright displays, returning almost 100% quantum yield.

Applications for FSQD polymers and polymer composites include point of purchase and point of sale posters, mobile device housings or logos, segmented displays, including infrared displays, absorbers for infrared sensors or detectors, and light emitting diodes (LEDs). The visible advantages inherent to FSQD polymers and polymer composites are attractive.

Accordingly, it is desirable to provide an improved free standing quantum dot light emitting display. Furthermore, other desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing figures, wherein like numerals denote like elements, and

FIG. 1 is a cross sectional view in accordance with a previously known display;

FIG. 2 is a block diagram in accordance with a first exemplary embodiment;

FIG. 3 is a cross sectional view in accordance with a second exemplary embodiment;

FIG. 4 is a cross sectional view in accordance with a third exemplary embodiment;

FIG, 5 is a top view of the exemplary embodiment of FIG. 4;

FIG. 6 is an isometric view of a portable communication device configured to incorporate the exemplary embodiments; and

FIG. 7 is a block diagram of one possible portable communication device of FIG. 7.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

Free standing quantum dots (FSQDs), also known as nano-crystals, are semiconductors composed of periodic groups of II-VI, III-V, or IV-VI materials, for example, CdS, CdSe, CdTe, ZnS, ZnSe, ZnTe, GaAs, GaP, GaAs, GaSb, HgS, HgSe, HgTe, InAs, InP, InSb, AlAs, AlP, AlSb. Alternative FSQDs materials that may be used include but are not limited to tertiary microcrystals such as InGaP, which emits in the yellow to red wavelengths (depending on the size) and ZnSeTe, ZnCdS, ZnCdSe, and CdSeS which emits from blue to green wavelengths. Multi-core structures are also possible such as ZnSe/ZnXS/ZnS, are also possible where X represents Ag, Cu, or Mn. The inner most core is made of ZnSe, followed by the second core layer of ZnXS, completed by an external shell made of ZnS.

FSQDs range in size from 2-10 nanometers in diameter (approximately 10²-10⁷ total number of atoms). At these scales, FSQDs have size-tunable band gaps, in other words there spectral emission depends upon size. Whereas, at the bulk scale, emission depends solely on the composition of matter. Other advantages of FSQDs include high photoluminescence quantum efficiencies, good thermal and photo-stability, narrow emission line widths (atom-like spectral emission), and compatibility with solution processing. FSQDs are manufactured conventionally by using colloidal solution chemistry.

FSQDs may be synthesized with a wider band gap outer shell, comprising for example ZnO, ZnS, ZnSe, ZnTe, CdO, CdS, CdSe, CdTe, MgS, MgSe, GaAs, GaN, GaP, GaAs, GaSb, HgO, HgS, HgSe, HgTe, InAs, InN, InP, InSb, AlAs, AlN, AlP, AlSb. The shell surrounds the core FSQDs and results in a significant increase in the quantum yield. Capping the FSQDs with a shell reduces non-radiative recombination and results in brighter emission. The surface of FSQDs without a shell has both free electrons in addition to crystal defects. Both of these characteristics tend to reduce quantum yield by allowing for non-radiative electron energy transitions at the surface. The addition of a shell reduces the opportunities for these non-radiative transitions by giving conduction band electrons an increased probability of directly relaxing to the valence band. The shell also neutralizes the effects of many types of surface defects. The FSQDs are more thermally stable than organic phosphors since UV light will not chemically breakdown FSQDs. The exterior shell can also serve as an anchor point for chemical bonds that can be used to modify and functionalize the surface.

Due to their small size, typically on the order of 10 nanometers or smaller, the FSQDs have larger band gaps relative to a bulk material. It is noted that the smaller the FSQDs, the higher the band gap. Therefore, when impacted by a photon (emissive electron-hole pair recombination), the smaller the diameter of the FSQDs, the shorter the wavelength of light will be released. Discontinuities and crystal defects on the surface of the FSQD result in non-radiative recombination of the electron-hole pairs that lead to reduced or completely quenched emission of the FSQD. An overcoating shell (example ZnS) having, e.g., a thickness of up to 5 monolayers and higher band gap compared to the core's band gap is optionally provided around the FSQDs core to reduce the surface defects and prevent this lower emission efficiency. The band gap of the shell material should be larger than that of the FSQDs to maintain the energy level of the FSQDs. Capping ligands (molecules) on the outer surface of the shell allow the FSQDs to remain in the colloidal suspension while being grown to the desired size. The FSQDs may then be placed within the display by a printing process, for example. Additionally, a light source (preferably a ultra violet (UV) source) is disposed to selectively provide photons to strike the FSQDs, thereby causing the FSQDs to emit a photon at a frequency comprising the specific color as determined by the size tunable band gap of the FSQDs.

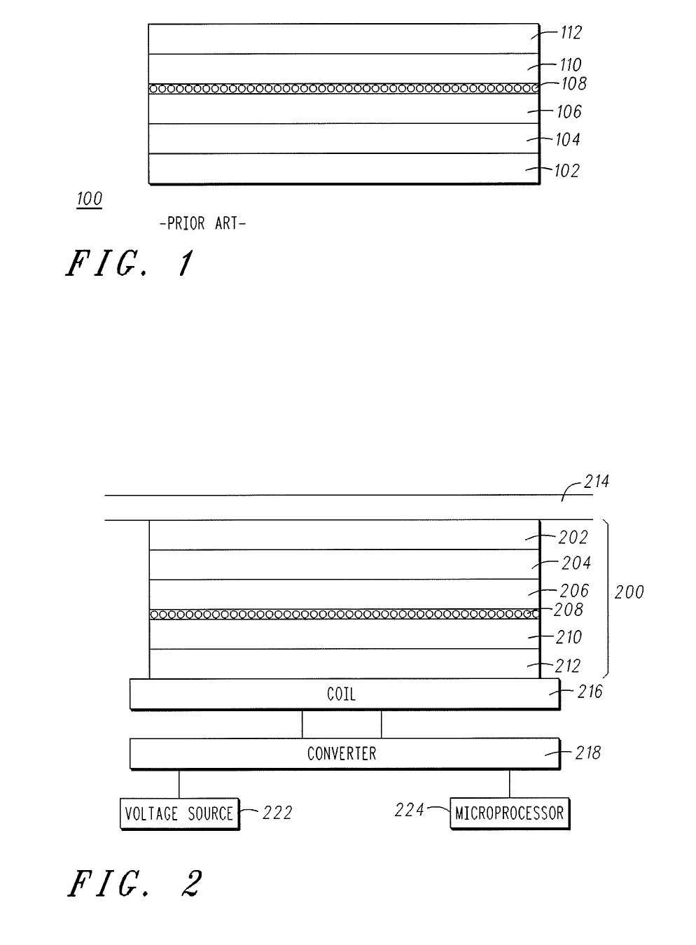

Referring to FIG. 1, a cross sectional view of a known light emitting device 100 includes a first electrode 104 formed on a substrate 102. A hole transport layer 106 is formed on the first electrode 104. A layer 108 of a plurality of FSQDs is formed on the hole transport layer 106. An electron injection layer 110 and a second electrode 112 are then formed over the layer 108. The substrate 102 typically comprises a transparent material. The first and second electrodes 104, 112 comprise a transparent material and function as an anode and a cathode, respectively.

In this previously known light emitting device 100, when the layer 108 of the plurality of FSQDs are impacted with light having a wavelength shorter that which would be emitted by the FSQDs, an electron in each of the FSQDs so impacted is excited to a higher level. Alternatively, a DC potential may be applied across the FSQDs to excite an electron to a higher level. When the electron falls back to its ground state, a photon is emitted having a wavelength determined by the size of the FSQD.

In accordance with the exemplary embodiments described herein, one or more layers of a plurality of FSQDs may be electrically driven (caused to emit photons) by an inductive coil. In one exemplary embodiment, the FSQDs may be driven by direct application of the electric field produced by the coil, which may be applied through a housing. This electric (electromagnetic) field results from the presence and motion of charged particles and exerts forces on them. A sub-discipline called electrodynamics describes the behavior of moving charged particles interacting with electromagnetic fields. This inductive coupling refers to the transfer of energy from one circuit component to another through a shared magnetic field. A change in current flow through one device, e.g., the coil, induces current flow in the other device, e.g., the light emitting device. The two devices may be separated as in the coil and light emitting device just mentioned or may be physically contained in a single unit, as in the primary and secondary sides of a transformer in a second exemplary embodiment. In this second exemplary embodiment, the FSQDs may be driven by the application of a current (after being converted from AC to DC) generated from a secondary coil by the application of an electric field from a primary coil. The wavelength of the emitted light comprises a color as determined by the diameter and composition of the FSQDs and may be used to illuminate, for example, icons, text, or the housing itself.

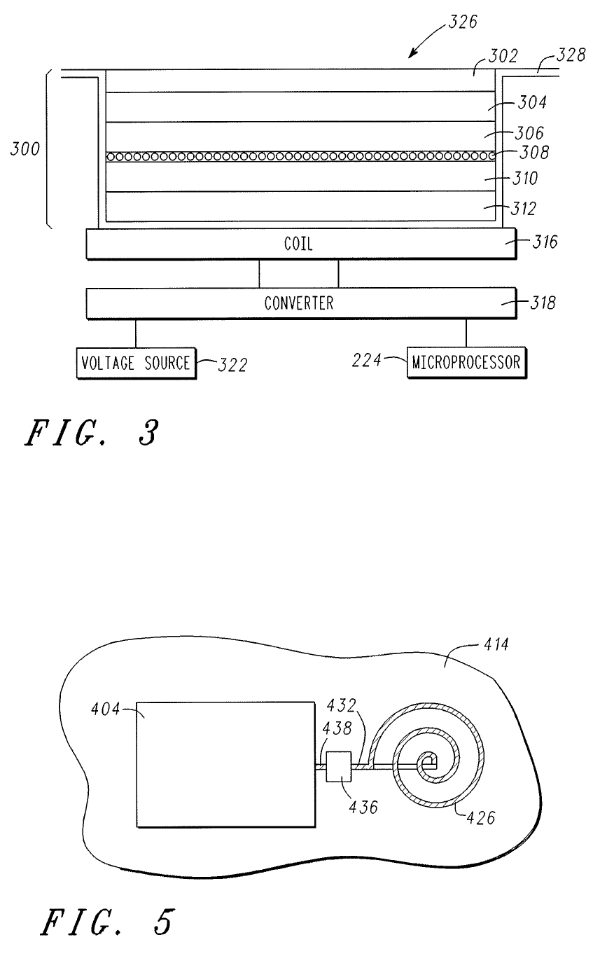

Referring to FIG. 2 and in accordance with a first exemplary embodiment, a cross sectional view of a light emitting device 200 includes a first electrode 204 (anode) formed on a substrate 202. A hole transport layer 206 is formed on the first electrode 204, but may alternatively comprise an electron blocking layer. A layer 208 of a plurality of FSQDs is formed on the hole transport layer 206. An electron injection layer 210 and a second electrode 212 (cathode) are then formed on the layer 208.

Though various lithography processes, e.g., photolithography, electron beam lithography, and various printing processes including imprint lithography ink jet printing, may be used to fabricate the light emitting device 200, a printing process is preferred. In the printing process, the FSQD ink in liquid form is printed in desired locations on the substrate. Ink compositions typically comprise four elements: 1) functional element, 2) binder, 3) solvent, and 4) additive. Graphic arts inks and functional inks are differentiated by the nature of the functional element, i.e. the emissive quantum dot. The binder, solvent and additives, together, are commonly referred to as the carrier which is formulated for a specific printing technology e.g. tailored rheology. The function of the carrier is the same for graphic arts and printed electronics: dispersion of functional elements, viscosity and surface tension modification, etc. One skilled in the art will appreciate that an expanded color range can be obtained by using more than three quantum dot inks, with each ink having a different mean quantum dot size. A variety of printing techniques, for example, Flexo, Gravure, Screen, inkjet may be used. The Halftone method, for example, allows the full color range to be realized in actual printing.

The substrate 202 comprises any transparent material, but may comprise, for example, glass, ceramic, insulated metal, polymers, and polymer composites. The first electrode 204 comprises a transparent material, preferably indium tin oxide, and function as an anode. The second electrode 212 comprises, for example, an opaque electron source material comprising, for example, magnesium and silver, and functions as a cathode. It is recognized that the substrate 202 may comprise a rigid structure or be flexible, and although it is disposed adjacent the first electrode 204 as shown, it may alternatively be opaque when disposed adjacent the second electrode 212. The hole transport layer 206 may be organic or inorganic and comprise, e.g., N,N0-diphenyl-N,N0-bis(3-methylphenyl)-(1,1 0-biphenyl)-4,4 0-diamine (TPD). The electron injection layer 210 may be either organic or inorganic and comprise, e.g.,tris-(8-hydroxyquinoline)aluminium or 3-(4-Biphenylyl)-4-phenyl-5-tert-butylphenyl-1,2,4-triazole (TAZ).

The light emitting device 200, and more specifically the substrate 202 in this embodiment, is disposed against the structure 214. The structure 214 may comprise any transparent material and may be rigid or flexible. Examples of the structure 214 include a poster board, such as used in advertising, and a portion of a housing for a portable electronic device.

A coil 216 is disposed contiguous to the light emitting device 200, for example against the second electrode 212 as shown in FIG. 2. A resonant converter 218 is coupled between the coil 216 and both a power source 222 and a microprocessor 224. When instructed by the microprocessor 224, the resonant converter 218 provides an alternating current to the coil 216. This alternating current flowing through the coil 216 provides an electric field (not shown).

When the layer 108 of the plurality of FSQDs is impacted by the electric field, an electron in each of the FSQDs so impacted is excited to a higher level. When the electron falls back to its ground state, a photon having a wavelength determined by the size of the FSQD is emitted and passes through the electrode 204 and the transparent structure 214. The first electrode 202, or a layer (not shown) disposed between the first electrode 202 and the structure 214, may be shaped or patterned wherein the photons exiting the structure 214 assume a desired pattern. Alternatively, a blocking layer (not shown) of an opaque material may block the light, thereby creating the pattern. Examples of the desired pattern may include, e.g., an envelope, text, or any know icons used in electronic devices. In another version of this first embodiment, a larger portion of the structure may receive the photons from the FSQDs, effectively providing a colored surface on the housing of a portable electronic device, for example.

FIG. 3 is a cross sectional view of a second exemplary embodiment, which includes a first electrode 304 (anode) formed on a substrate 302. A hole transport layer 306 is formed on the first electrode 304, but may alternatively comprise an electron blocking layer. A layer 308 of a plurality of FSQDs is formed on the hole transport layer 306. An electron injection layer 310 and a second electrode 312 (cathode) are then formed over the layer 308. The substrate 302 comprises any transparent material, but may comprise, for example, glass, ceramic, insulated metal, polymers, and polymer composites. The first electrode 304 comprises a transparent material, preferably indium tin oxide, and function as an anode. The second electrode 312 comprises, for example, an opaque electron source material comprising, for example, magnesium and silver, and functions as a cathode. It is recognized that the substrate 302 may comprise a rigid structure or be flexible, and although is disposed adjacent the first electrode 304, it may alternatively be disposed adjacent the second electrode 312. The light emitting device 300 is disposed against the structure 314, and may be positioned within an indent 326 as shown, or may extend above the structure 314. The structure 314 may comprise any transparent material and may be rigid or flexible. Although the light emitting device 300 is thin, e.g., in the range of 0.001 to 1.0 millimeters thick, by placing the light emitting device 300 in the indent 326, a smoother surface 328 is realized.

A coil 316 is disposed on a side of the structure 314 opposed to the second electrode 312, but near the layer of FSQDs 308. A resonant converter 318 is coupled between the coil 316 and both a power source 322 and a microprocessor 324. When instructed by the microprocessor 324, the resonant converter 318 provides an alternating current to the coil 316. This alternating current flowing through the coil 316 provides an electric field (not shown) which will exist through and on the other side of the structure 314.

When the layer 108 of the plurality of FSQDs is impacted by the electric field, an electron in each of the FSQDs so impacted is excited to a higher level. When the electron falls back to its ground state, a photon having a wavelength determined by the size of the FSQD is emitted and passes through the transparent structure 214. The first electrode 304, or a layer (not shown) disposed between the first electrode 304 and the structure 314, may be shaped or patterned wherein the photons exiting the structure 314 assume a desired pattern. Examples of the desired pattern may include, e.g., an envelope, text, or any know icons used in electronic devices.

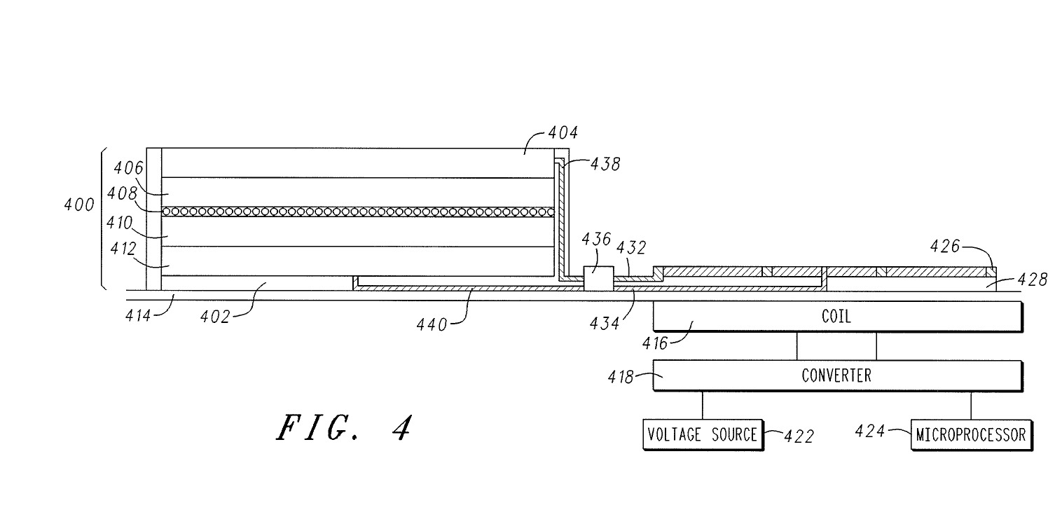

Referring to FIGS. 4 and 5, a third exemplary embodiment of a light emitting device 400 includes a first electrode 404 (anode) formed on a hole transport layer 406. A layer 408 of a plurality of FSQDs is disposed between the hole transport layer 406 and an electron injection layer 410. A second electrode 412 (cathode) is disposed between the layer 408 and a substrate 402. The substrate 402 comprises any transparent material, but may comprise, for example, glass, ceramic, insulated metal, polymers, and polymer composites. The first electrode 404 comprises a transparent material, preferably indium tin oxide, and function as an anode. The second electrode 412 comprises, for example, an opaque electron source material comprising, for example, magnesium and silver, and functions as a cathode. It is recognized that the substrate 402 may comprise a rigid structure or be flexible, and although is disposed adjacent the first electrode 404, it may alternatively be disposed adjacent the first electrode 404. The light emitting device 400 is disposed against the structure 414. The structure 414 may comprise any transparent material and may be rigid or flexible.

A primary coil 416 is disposed on a side of the structure 414 opposed to the light emitting device 400. A resonant converter 418 is coupled between the coil 416 and both a power source 422 and a microprocessor 424. A secondary coil 426 is disposed a side of the structure 414 opposed by the primary coil 416, and formed over a dielectric material 428. Electrical conductors 432, 434 are formed within the dielectric material 428 and are coupled to the respective ends of the secondary coil 426. When instructed by the microprocessor 424, the resonant converter 418 provides an alternating current to the coil 416. This alternating current flowing through the coil 416 provides an electric field (not shown) which will project through and on the other side of the structure 414. This electric field within the secondary coil 426 will generate an AC current to an AC to DC converter 436. A DC voltage is provided by electrical conductors 438, 440 to the first and second electrodes 404, 412, respectively.

When the layer 408 of the plurality of FSQDs are impacted by the electric field having an electron in each of the FSQDs so impacted is excited to a higher level. When the electron falls back to its ground state, a photon having a wavelength determined by the size of the FSQD is emitted and passes out through the anode 404. The first electrode 404, or a layer (not shown) disposed over the first electrode 404, may be shaped or patterned wherein the photons exiting the light emitting device 400 assume a desired pattern. Examples of the desired pattern may include, e.g., an envelope, text, or any know icons used in electronic devices.

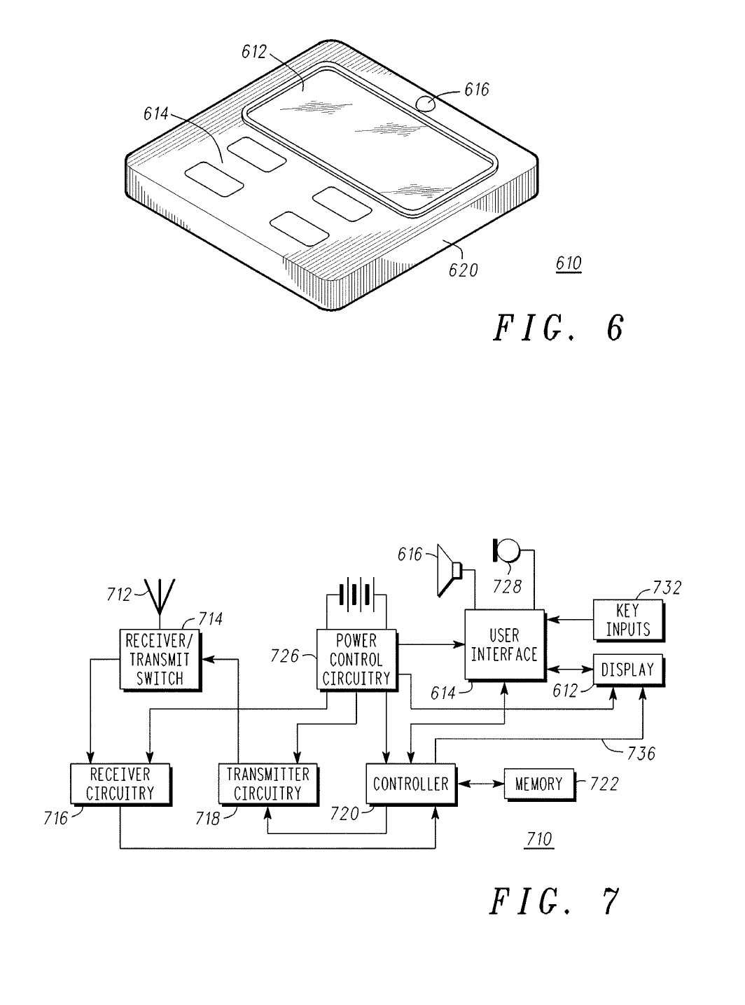

Referring to FIG. 6, a portable electronic device 610 comprises a display 612, a control panel 614, and a speaker 616 encased in a housing 620. Some portable electronic devices 610, e.g., a cell phone, may include other elements such as an antenna, a microphone, and a camera (none shown). In the exemplary embodiments described herein, the display 612 comprises a free standing quantum dot photon emitting technology. The exemplary embodiment may comprise any type of electronic device, for example, a PDA, a mobile communication device, and gaming devices. Furthermore, while the preferred exemplary embodiment of a portable electronic device is described as a mobile communication device, other embodiments are envisioned, such as flat panel advertising screens, point of purchase and point of sale posters, mobile device housings or logos, segmented displays, including infrared displays, electronic shelf labels, embedded displays for bio-sensors and personal health monitoring wearable displays, and embedded displays in smart cards.

Referring to FIG. 7, a block diagram of a portable electronic device 710 such as a cellular phone, in accordance with the exemplary embodiment is depicted. Though the exemplary embodiment is a cellular phone, the display described herein may be used with any electronic device in which information, colors, or patterns are to be presented. The portable electronic device 710 includes an antenna 712 for receiving and transmitting radio frequency (RF) signals. A receive/transmit switch 714 selectively couples the antenna 712 to receiver circuitry 716 and transmitter circuitry 718 in a manner familiar to those skilled in the art. The receiver circuitry 716 demodulates and decodes the RF signals to derive information therefrom and is coupled to a controller 720 for providing the decoded information thereto for utilization thereby in accordance with the function(s) of the portable communication device 710. The controller 720 also provides information to the transmitter circuitry 718 for encoding and modulating information into RF signals for transmission from the antenna 712. As is well-known in the art, the controller 720 is typically coupled to a memory device 722 and a user interface 114 to perform the functions of the portable electronic device 710. Power control circuitry 726 is coupled to the components of the portable communication device 710, such as the controller 720, the receiver circuitry 716, the transmitter circuitry 718 and/or the user interface 114, to provide appropriate operational voltage and current to those components. The user interface 114 includes a microphone 728, a speaker 116 and one or more key inputs 732, including a keypad. The user interface 114 may also include a display 112 which could include touch screen inputs. The display 112 is coupled to the controller 720 by the conductor 736 for selective application of voltages in some of the exemplary embodiments described above.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. An apparatus comprising:
a light emitting device including a plurality of quantum dots; and
a first coil disposed contiguous to the light emitting device, wherein an electric field generated by the first coil causes the plurality of quantum dots to emit photons.

2. The apparatus of claim 1 further comprising a transparent structure to which the light emitting device is attached and wherein the photons pass through the transparent structure.

3. The apparatus of claim 1 further comprising a structure having the light emitting device mounted thereon and the first coil being disposed on a side of the structure opposed to the light emitting device.

4. The apparatus of claim 3 wherein the structure defines an indent having the light emitting device disposed therein.

5. The apparatus of claim 1 wherein the structure is a housing of a portable electronic device.

6. The apparatus of claim 1 further comprising:
a structure having the light emitting device and the first coil mounted on a first side thereof; and
a second coil disposed on a second side of the structure, wherein an electric field generated by the second coil interacts with the first coil, the first coil providing a current to cause the plurality of quantum dots to emit photons.

7. The apparatus of claim 6 wherein the second coil provides an AC current, the apparatus further comprising an AC/DC converter disposed on the first side and coupled between the AC/DC converter and the light emitting device.

8. An apparatus comprising:
a housing;
a light emitting device disposed contiguous to the housing, comprising:
a cathode;
a electron transparent layer formed over the cathode;
at least one layer of a plurality of quantum dots disposed over the electron transport layer;
a hole transport layer formed over the plurality of quantum dots; and
an anode formed over the hole transport layer;
a first coil disposed contiguous to the light emitting device, wherein an electric field generated by the first coil causes the plurality of quantum dots to emit photons.

9. The apparatus of claim 8 wherein the housing is transparent, the anode is adjacent a first side of the housing, the photons passing through the transparent housing; and the first coil is disposed on the first side of the housing.

10. The apparatus of claim 8 wherein the cathode is adjacent a second side of the transparent housing and the first coil is disposed on the first side of the transparent housing.

11. The apparatus of claim 8 wherein the cathode is adjacent a second side of the housing and the first coil is disposed on the second side of the housing, the apparatus further comprising:
a second coil disposed on a first side of the housing so that an electric field generated by the second coil creates a current in the first coil;
a first electrical conductor coupled between a first end of the first coil and the cathode; and
a second electrical conductor coupled between a second end of the first coil and the anode.

12. The apparatus of claim 11 further comprising an AC to DC converter coupled between the second coil and the first and second electrical conductors.

13. A method of emitting photons from a light emitting device, comprising:
supplying an alternating current to a coil for generating an electric field; and
subjecting a plurality of free standing quantum dots to the electric field to cause the free standing quantum dots to emit photons.

14. The method of claim 13 wherein the light emitting device comprises a cathode, an electron transparent layer formed over the cathode, the plurality of free standing quantum dots disposed over the electron transport layer, a hole transport layer formed over the plurality of free standing quantum dots; and an anode formed over the hole transport layer and disposed adjacent to a transparent structure, the method further comprising:
passing the photons through the transparent structure to which the free standing quantum dots are attached.

15. The method of claim 13 wherein the transparent structure comprising a housing of an electronic device and the passing step comprises passing the photons through the housing.

16. The method of claim 13 wherein the light emitting device comprises a cathode disposed adjacent to a structure, an electron transparent layer formed over the cathode, the plurality of free standing quantum dots disposed over the electron transport layer, a hole transport layer formed over the plurality of free standing quantum dots; and an anode formed over the hole transport layer, wherein the subjecting step comprises:
applying the electric field through the structure.
